(19) United States
(12) Patent Application Publication
(10) Pub. No.: US 2026/0333837 A1
(43) Pub. Date: Oct. 22, 2026

(54) BOTTOM DIELECTRIC ISOLATION LAYER AS AN ESL AND A BACKSIDE SELF-ALIGNMENT FEATURE

(71) Applicant: Taiwan Semiconductor Manufacturing Company, Ltd., Hsinchu (TW)

(72) Inventors: Che Chi Shih, Taoyuan City (TW); Zhi-Chang Lin, Zhubei City (TW); Kuan-Kan Hu, Hsinchu (TW); Ku-Feng Yang, Baoshan Township (TW); Szuya Liao, Zhubei (TW)

(21) Appl. No.: 19/725,295

(22) Filed: Jun. 30, 2026

Related U.S. Application Data
(63) Continuation of application No. 19/010,714, filed on Jan. 6, 2025.
(60) Provisional application No. 63/695,109, filed on Sep. 16, 2024.

(51) Int. Cl. H10D 84/01; H10D 30/00; H10D 30/01; H10D 30/43; H10D 62/10; H10D 62/13; H10D 64/01; H10D 84/85

(52) U.S. Cl. CPC H10D 84/0188; H10D 30/014; H10D 30/019; H10D 30/43; H10D 30/501; H10D 62/121; H10D 62/151; H10D 64/017; H10D 84/017; H10D 84/851

(57) ABSTRACT

A method includes forming a wafer comprising a substrate, a sacrificial layer over the substrate, and a multilayer stack over the sacrificial layer. The method further includes performing a first etching process on the multilayer stack and the sacrificial layer to form a patterned multilayer stack, replacing a part of the sacrificial layer in the patterned multilayer stack with a bottom dielectric isolation layer, performing a second etching process on the patterned multilayer stack to form a source/drain recess, wherein a surface of the bottom dielectric isolation layer is exposed to the source/drain recess, and forming a lower source/drain region and an upper source/drain region in the source/drain recess. The substrate is removed to reveal the bottom dielectric isolation layer. A portion of the bottom dielectric isolation layer is removed to form a backside contact opening. A source/drain silicide layer is formed in the backside contact opening.

### PRIORITY CLAIM AND CROSS-REFERENCE

This application is a continuation of U.S. patent application Ser. No. 19/010,714 filed on Jan. 6, 2025, which application claims the benefit of the following provisionally filed U.S. Patent Application No. 63/695,109, filed on Sep. 16, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 18A, 18B, and 18C illustrate the views of intermediate stages in the formation of Complementary Field-Effect Transistors (CFETs) in accordance with some embodiments.

FIG. 19 illustrates a process flow for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) including a bottom dielectric isolation layer and the formation methods are provided. In accordance with some embodiments, a bottom dielectric isolation layer is formed underlying a multilayer stack. The multilayer stack is then used to form a CFET, which includes an upper FET and a lower FET. The bottom dielectric isolation layer is used as an etch stop layer in the formation of source/drain recesses, in which source/drain regions are formed. The bottom dielectric isolation layer may also be implanted, so that the implanted portions may be used as self-aligned features, and may be removed from the backside of the respective wafer to form backside contact openings. Backside contact plugs are formed in the backside contact openings, and are thus self-aligned to the lower source/drain regions.

Although the example embodiments use GAA FETs as the upper FETs and the lower FETs, the embodiments may also be applied to the CFETs comprising other FETs such as Fin Field-Effect Transistors (FinFETs), planar transistors, the like, or the combinations of the GAA FETs, FinFETs, and planar transistors. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

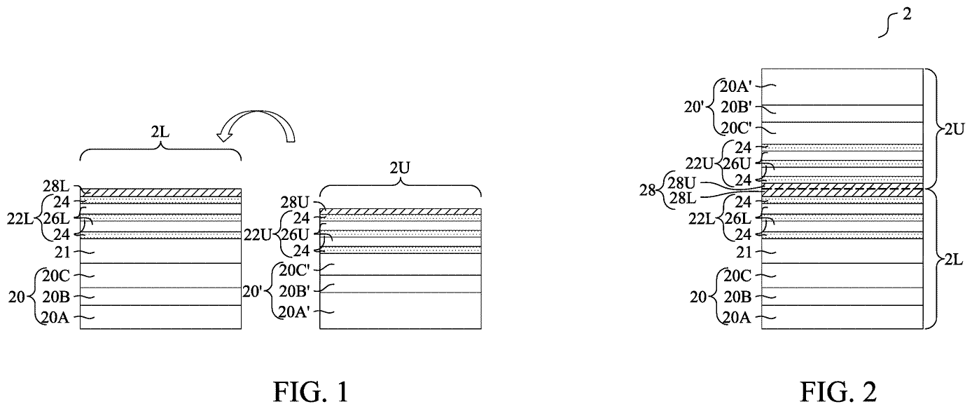

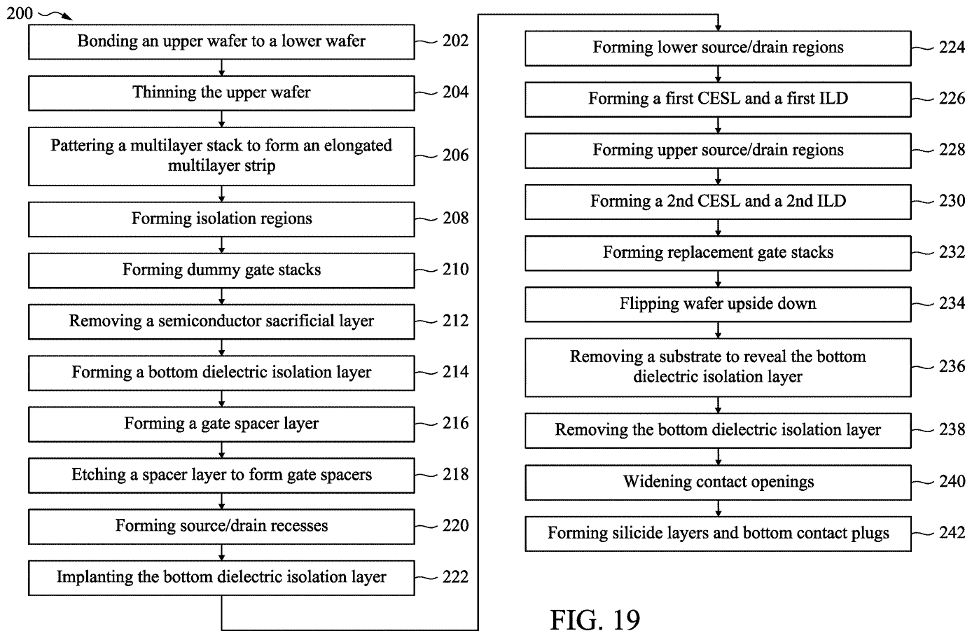

FIGS. 1 through 18A, 18B, and 18C illustrate the cross-sectional views of intermediate stages in the formation of CFETs in accordance with some embodiments. The corresponding processes are also reflected schematically in the process flow 200 as shown in FIG. 19.

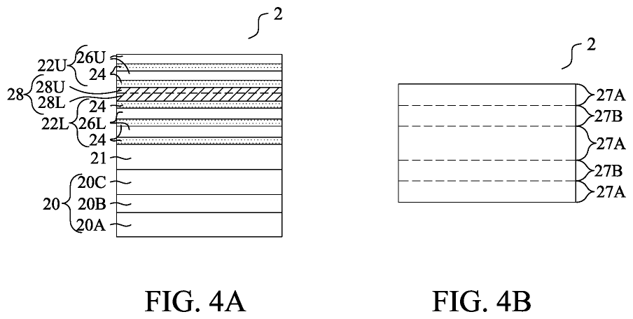

Referring to FIGS. 1 through 4B, wafer 2 (FIG. 4A), which includes substrate 20, is formed. In accordance with some embodiments, substrate 20 is a bulk substrate formed of a homogeneous semiconductor material such as silicon. In accordance with alternative embodiments, as shown in FIG. 1, substrate 20 is a composite substrate including a composite structure. The composite structure may include semiconductor layers 20A and 20C, which may be silicon layers, and stop layer 20B, which may be formed of or comprise a semiconductor material such as silicon germanium. Alternatively, stop layer 20B may comprise a dielectric material such as silicon nitride, a silicon oxide, or the like.

A multilayer stack 22 (FIG. 4A) is formed over the substrate 20. The multilayer stack 22 includes alternating dummy semiconductor layers 24 and semiconductor layers 26 (including lower semiconductor layers 26L and upper semiconductor layers 26U). Multilayer stack 22 includes upper multilayer stack portion 22U (also referred to as upper multilayer stack 22U) and lower multilayer stack portion 22L (also referred to as lower multilayer stack 22L). Lower semiconductor layers 26L and upper semiconductor layers 26U are for forming lower FETs and upper FETs, respectively.

The dummy semiconductor layers 24 are formed of a semiconductor material, which may be selected from the candidate semiconductor materials of the substrate 20. The semiconductor layers 26 (including the lower semiconductor layers 26L and upper semiconductor layers 26U) are formed of one or more semiconductor material(s) different from the material of dummy semiconductor layers 24. The semiconductor material(s) may also be selected from the candidate semiconductor materials of the substrate 20. In some embodiments, dummy semiconductor layers 24 are formed of or comprise silicon germanium, and semiconductor layers 26 are formed of or comprise silicon.

Dielectric layer 28 is located between upper multilayer stack portion 22U and lower multilayer stack portion 22L. Dielectric layer 28 may be in contact with an overlying dummy semiconductor layer 24 and an underlying dummy semiconductor layer 24. In accordance with some embodiments, the entire dielectric layer 28 is formed of a homogeneous material such as silicon oxide, silicon nitride, silicon carbide, aluminum oxide, aluminum nitride, titanium oxide, or the like.

In accordance with alternative embodiments, the dielectric layer 28 comprises a lower sub layer 28L and an upper sub layer 28U, which may be formed of a same dielectric material or different dielectric materials. Regardless of whether the lower sub layer 28L and the upper sub layer 28U are formed of the same dielectric material or different dielectric materials, the lower sub layer 28L and the upper sub layer 28U may (or may not) have a distinguishable interface in between.

In accordance with some embodiments, the upper multilayer stack portion 22U and the lower multilayer stack portion 22L of multilayer stack 22 are formed separately, and are bonded together to form the wafer 2 as shown in FIG. 2. An example formation process is discussed below briefly referring to FIGS. 1 through 3.

FIG. 1 illustrates example initial structures for forming wafer 2. As shown in FIG. 1, lower wafer 2L is formed, which includes substrate 20, semiconductor sacrificial layer 21, lower multilayer stack 22L, and dielectric layer 28L formed thereon.

In accordance with some embodiments, semiconductor sacrificial layer 21 is formed of a semiconductor material that is different from the material of dummy semiconductor layers 24 and semiconductor layers 26L and 26U. In accordance with some embodiments, semiconductor sacrificial layer 21 may comprise a semiconductor material such as silicon germanium, with the germanium atomic percentage being greater than the germanium atomic percentages of both of the dummy semiconductor layers 24 and semiconductor layers 26. Accordingly, semiconductor sacrificial layer 21 is referred to as semiconductor sacrificial layer 21, while it may also be formed of other materials such as dielectric materials. In accordance with some embodiments, the germanium percentage in semiconductor sacrificial layer 21 may be in the range between about 30 percent and about 50 percent.

Lower multilayer stack portion 22L may be grown over the semiconductor sacrificial layer 21, and may be grown layer-by-layer through epitaxy. In accordance with some embodiments, the dummy semiconductor layers 24 in the lower multilayer stack portion 22L (and in upper multilayer stack portion 22U) may be in the range between about 10 percent and about 35 percent. The semiconductor layers 26L may be formed of silicon (free from germanium), or may comprise silicon germanium with a germanium atomic percentage that is further lower than the germanium atomic percentage of the dummy semiconductor layers 24.

Dielectric layer 28L (also referred to as a dielectric bond layer or a dielectric isolation layer) is then deposited over the lower multilayer stack 22L. In accordance with some embodiments, dielectric layer 28L comprises a silicon-containing dielectric material and/or an oxide. The candidate materials may include silicon oxide, silicon nitride, silicon oxynitride, silicon oxycarbide, AlO, TiO, HfO₂, Al₂O₃, LaO, ZrO, or the like. or the like. Other dielectric materials such as AlN may also be used.

FIG. 1 further illustrates the formation of upper wafer 2U, which includes substrate 20′, upper multilayer stack 22U, and dielectric layer 28U formed thereon. In accordance with some embodiments, substrate 20′ has a similar or a same structure as substrate 20. For example, substrate 20′ may be a composite substrate including a composite structure. The composite structure may include semiconductor layers 20A′ and 20C′, which may be silicon layers, and stop layer 20B′, which may be formed of or comprise a semiconductor material such as a silicon germanium, or may be formed of or comprise a dielectric material such as silicon nitride, silicon oxide, or the like. The structures, materials, and formation methods of the features in upper multilayer stack 22U may be essentially the same as the corresponding features in lower multilayer stack 22L.

Referring to FIG. 2, wafer 2U is bonded to wafer 2L to form wafer 2. The respective process is illustrated as process 202 in the process flow 200 as shown in FIG. 19. The bonding may be achieved by bonding dielectric layer 28U to dielectric layer 28L. The resulting dielectric layers 28L and 28U are individually and collectively referred to as dielectric layers 28 or bond layers 28. The bonding may be achieved through fusion bonding, in which Si—O—Si bonds are formed.

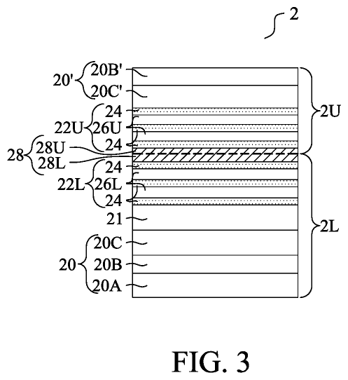

Next, a thinning process is performed to remove the substrate 20'. The respective process is illustrated as process 204 in the process flow 200 as shown in FIG. 19. The thinning may be performed through a Chemical Mechanical Polish (CMP) process and/or an etching process(es). For example, a CMP process may be performed to remove semiconductor layer 20A′, with stop layer 20B′ being used as the CMP stop layer. The resulting structure is shown in FIG. 3.

In FIG. 3, a dashed line is drawn between dielectric layers 28L and 28U to indicate that there may be or may not be a distinguishable interface in between, and/or dielectric layers 28L and 28U may be formed of the same dielectric material or different dielectric materials.

Next, an etching process or a CMP process may be performed to remove stop layer 20B′ and semiconductor layer 20C′, with the etching process stopping on semiconductor layer 26U. Alternatively, the etching or the CMP may stop on a dummy semiconductor layer 24. The exposed dummy semiconductor layer 24 is then removed, exposing a semiconductor layer 26U. The resulting structure is shown in FIG. 4A. FIG. 4B illustrates a top view of wafer 2.

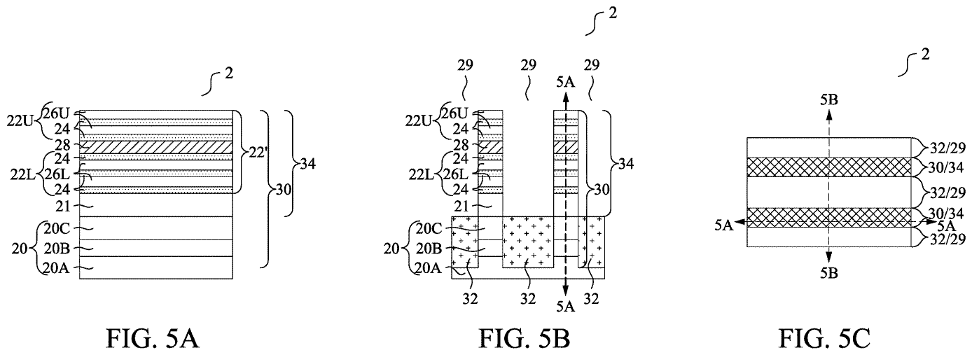

FIGS. 5A and 5B illustrate the patterning of multi-layer stack 22 and semiconductor sacrificial layer 21 through an etching process(es) to form elongated multilayer strips 30. The respective process is illustrated as process 206 in the process flow 200 as shown in FIG. 19. FIG. 5C illustrates a top view of wafer 2. FIGS. 5A and 5B illustrate the cross-sectional views of the cross-sections 5A-5A and 5B-5B, respectively. The etched portions of wafer 2 are marked as the portions 27A in FIG. 4B, while the portions 27B as shown in FIG. 4B are not etched. Accordingly, recesses 29 (FIGS. 5B and 5C) are formed between elongated multilayer strips 30. Each of the elongated multilayer strips 30 includes a semiconductor strip (a portion of the original substrate 20) and multi-layer stack 22′, which is the remaining portion of multi-layer stack 22. The remaining portions 22′ of multi-layers stack 22 are also referred to as nanostructures hereinafter.

Multi-layer stack 22′ includes the remaining portions of dummy nanostructures 24, lower semiconductor nanostructures 26L, dielectric layer 28, and upper semiconductor nanostructures 26U. The etching may be performed by any acceptable etch process, such as a Reactive Ion Etch (RIE), Neutral Beam Etch (NBE), the like, or a combination thereof. The etching may be anisotropic. The remaining portions of lower semiconductor nanostructures 26L and the upper semiconductor nanostructures 26U may further be individually and collectively referred to as semiconductor nanostructures 26.

The lower semiconductor nanostructures 26L will act as channel regions for lower nanostructure-FETs of the CFETs. The upper semiconductor nanostructures 26U will act as channel regions for upper nanostructure-FETs of the CFETs. The dielectric layer 28 may define boundaries of the lower nanostructure-FETs and the upper nanostructure-FETs.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process.

In FIGS. 5B and 5C, isolation regions 32 are formed over the substrate 20 and between adjacent elongated multilayer strips 30. The respective process is illustrated as process 208 in the process flow 200 as shown in FIG. 19. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof.

The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the isolation regions 32 include silicon oxide formed by an FCVD process, followed by an anneal process.

Further referring to FIGS. 5B and 5C, isolation regions 32 are recessed. Some upper portions of elongated multilayer strips 30 (including multi-layer stacks 22′) protrude higher than the remaining isolation regions 32 to form protruding fins 34. The sidewalls of semiconductor sacrificial layer 21 are exposed.

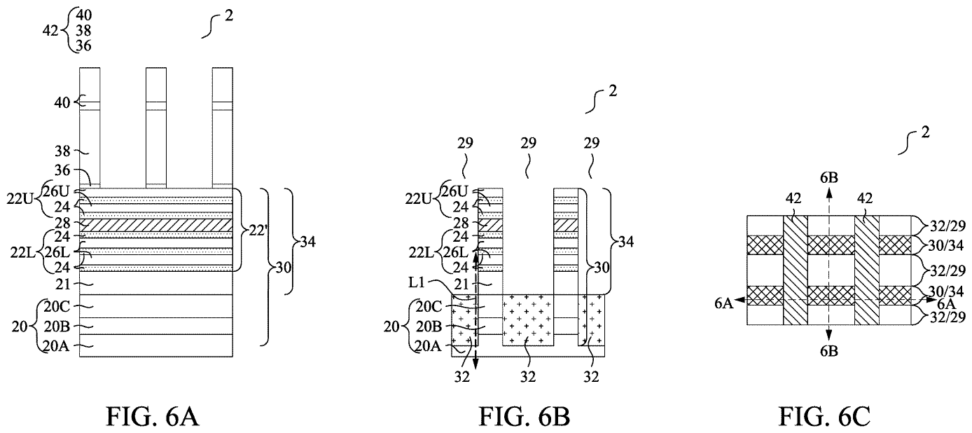

In FIGS. 6A, 6B, and 6C, dummy gate stacks 42 are formed. The respective process is illustrated as process 210 in the process flow 200 as shown in FIG. 19. Each of dummy gate stacks 42 includes dummy dielectric layer 36, dummy gate layer 38, and mask layer(s) 40. In the formation process, dummy dielectric layer 36 is first formed on the protruding fins 34. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer(s) 40 is formed over the planarized dummy gate layer 38, and may include, for example, silicon nitride, silicon oxynitride, or the like.

Next, the mask layer 40 may be patterned through photolithography and etching processes to form a mask, which is then used to etch and pattern dummy gate layer 38, and possibly dummy dielectric layer 36. A resulting structure is shown in FIGS. 6A, 6B, and 6C. FIG. 6C illustrate a top view of wafer 2. FIGS. 6A and 6B illustrate the cross-sections 6A-6A and 6B-6B, respectively, in FIG. 6C. The remaining portions of mask layer 40, dummy gate layer 38, and dummy dielectric layer 36 form dummy gate stacks 42.

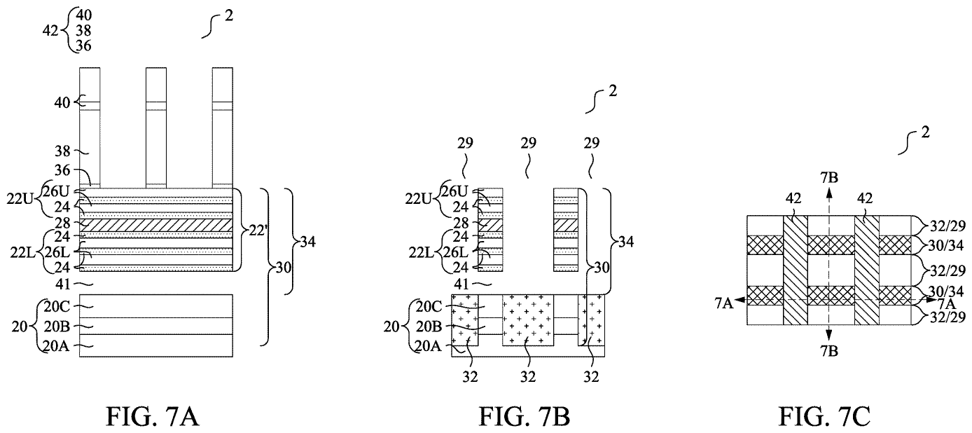

In FIGS. 7A, 7B, and 7C, an etching process is performed to remove semiconductor sacrificial layer 21, and to form recesses 41. The respective process is illustrated as process 212 in the process flow 200 as shown in FIG. 19. FIGS. 7A and 7B illustrate the cross-sections 7A-7A and 7B-7B, respectively, in FIG. 7C. The etching is performed through the exposed sidewalls of the protruding fins 34 (FIG. 6B). It is appreciated that as shown in FIGS. 7A and 7C, since gate stacks 42 are on the sidewalls of elongated multilayer strips 30, multilayer stacks 22L and 22U are supported, and thus do not collapse.

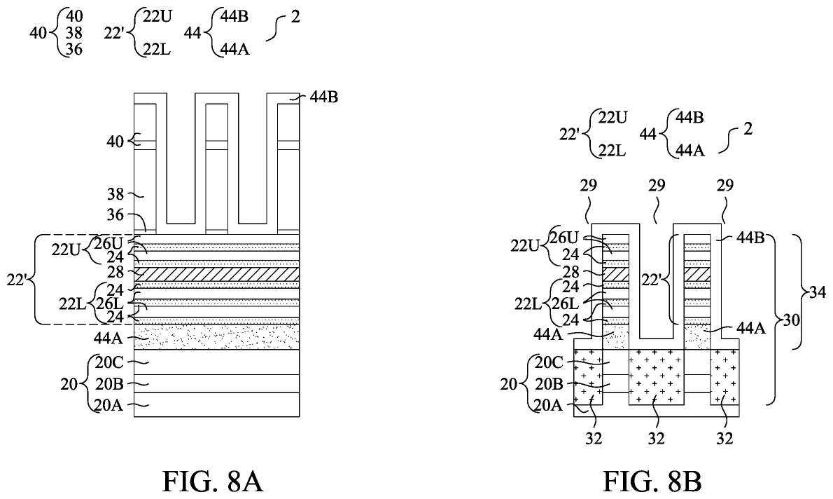

In FIGS. 8A and 8B, which illustrate the same cross-sections as cross-sections 7A-7A and 7B-7B, respectively, in FIG. 7C, spacer layer 44 is deposited. In accordance with some embodiments, spacer layer 44 is deposited through a conformal deposition process, and hence includes the portions filling recesses 41, and the portions on the sidewalls and the top surface of the exposed features. The applicable dielectric materials of the spacer layer 44 may include silicon oxy-carbo-nitride, silicon nitride, silicon oxycarbide, or the like, which may be formed by a deposition process such as CVD, ALD, or the like.

The portions of the spacer layer 44 filling recesses 41 are referred to as bottom dielectric isolation layers 44A hereinafter. The respective formation process is illustrated as process 214 in the process flow 200 as shown in FIG. 19. The portions of spacer layer 44 outside of recesses 41 are referred to as gate spacer layer 44B. The respective formation process is illustrated as process 216 in the process flow 200 as shown in FIG. 19.

In accordance with some embodiments, the bottom dielectric isolation layers 44A is formed in a same deposition process as, and thus comprises the same dielectric material as, gate spacer layer 44B. In accordance with alternative embodiments, the bottom dielectric isolation layers 44A is formed in a different deposition process than gate spacer layer 44B. Accordingly, the bottom dielectric isolation layers 44A and gate spacer layer 44B may be formed of the same or different dielectric materials. There thus may be, or may not be, distinguishable interfaces between the bottom dielectric isolation layers 44A and gate spacer layer 44B.

In accordance with some embodiments, the thickness ratio of the thickness of upper multilayer stack 22U (or lower multilayer stack 22L) to the thickness (height) of bottom dielectric isolation layers 44A may be in the range between about 0.5 and about 5. The thickness ratio of the thickness of dielectric layer 28 to the thickness (height) of bottom dielectric isolation layers 44A may be in the range between about 0.5 and about 10.

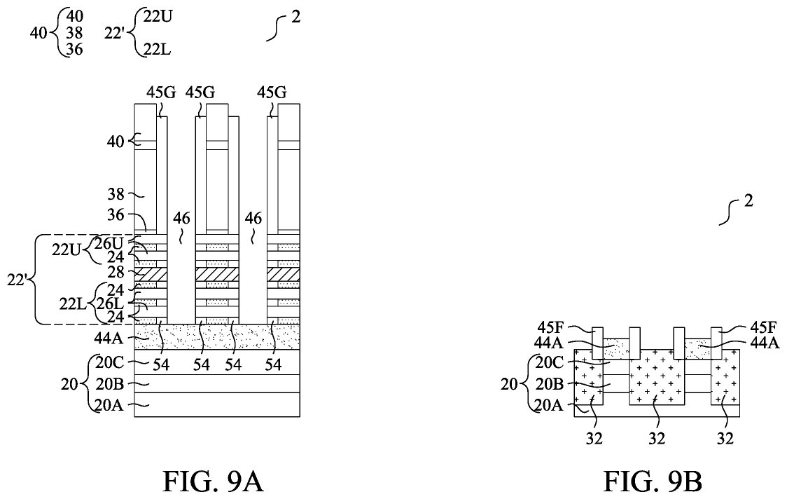

Next, an anisotropic etching process is performed to remove the horizontal portions of the gate spacer layer 44B. The remaining portions of the gate spacer layer 44B are referred to as gate spacers 45G and fin spacers 45F, which are on the sidewalls of dummy gate stacks 42 (FIG. 9A) and multilayer stacks 22′. The resulting structure is illustrated in FIGS. 9A and 9B. The respective process is illustrated as process 218 in the process flow 200 as shown in FIG. 19.

Next, as also shown in FIGS. 9A and 9B, source/drain recesses 46 are formed by etching the portions of the multilayer stacks 22′ not directly underlying dummy gate stacks 42 and gate spacers 45G. The respective process is illustrated as process 220 in the process flow 200 as shown in FIG. 19. In the etching process, bottom dielectric isolation layers 44A are used as etch stop layers. Since the semiconductor sacrificial layer 21 (FIG. 4A), based on which bottom dielectric isolation layers 44A are formed, is planar throughout wafer 2, the bottoms of source/drain recesses 46 throughout wafer 2 are at the same level, and through-wafer uniformity is improved.

The bottom surfaces of the source/drain recesses 46 may be at a level above, below, or level with the top surfaces of the isolation regions 32. In the etching processes, the gate spacers 45G and the dummy gate stacks 42 mask some portions of the multilayer stacks 22′. The etching may include a single etch process or multiple etch processes.

As may be realized from FIGS. 9A and 9B, when the multilayer stack 22′ is etched, fin spacers 45F are also recessed accordingly, and the resulting structure is shown in FIG. 9B.

Further referring to FIGS. 9A and 9B, inner spacers 54 are formed. The formation process may include laterally recessing dummy nanostructures 24 to form lateral recesses, and filling the lateral recesses with a dielectric material(s) to form inner spacers 54. The dielectric material may include silicon oxycarbonitride, silicon oxycarbide, silicon oxynitride, or the like. The dielectric material may be formed by a deposition process, such as ALD, CVD, or the like. The etching of the dielectric material may be isotropic.

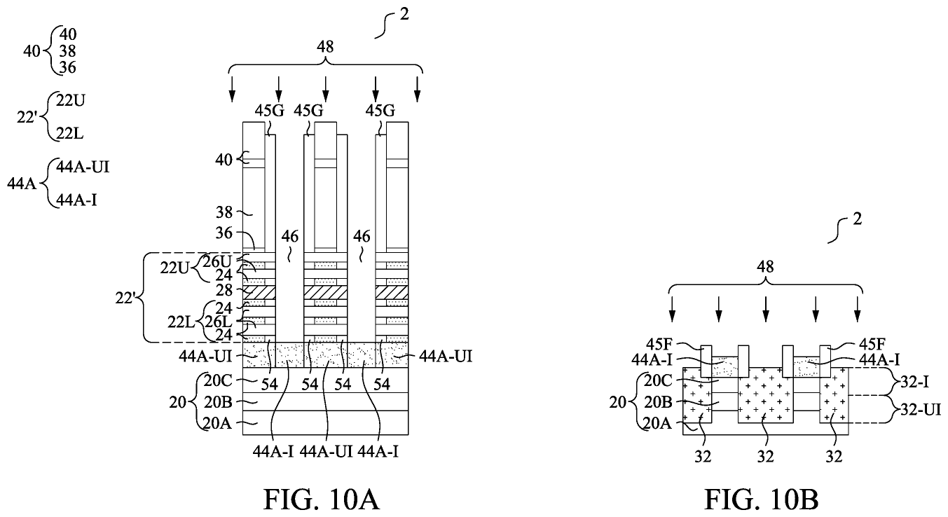

Referring to FIGS. 10A and 10B, an implantation process 48 is performed. In accordance with some embodiments, the implanted dopant comprises Si, C, O, P, N, B, F, As, or combinations thereof. The respective process is illustrated as process 222 in the process flow 200 as shown in FIG. 19. The implantation process 48 may include a vertical implantation without being slanted. The dopant concentration in the implanted regions may be in the range between about 1E18/cm³ and about 1E22/cm³.

The implanted portions of bottom dielectric isolation layer 44A are the exposed portions that are not directly underlying the dummy gate stacks 42 and gate spacers 45G. The implanted portions are referred to as the implanted portions 44A-I hereinafter. Some portions of bottom dielectric isolation layer 44A directly underlying the dummy gate stacks 42 and gate spacers 45G are not implanted, and are referred to as un-implanted portions 44A-UI hereinafter.

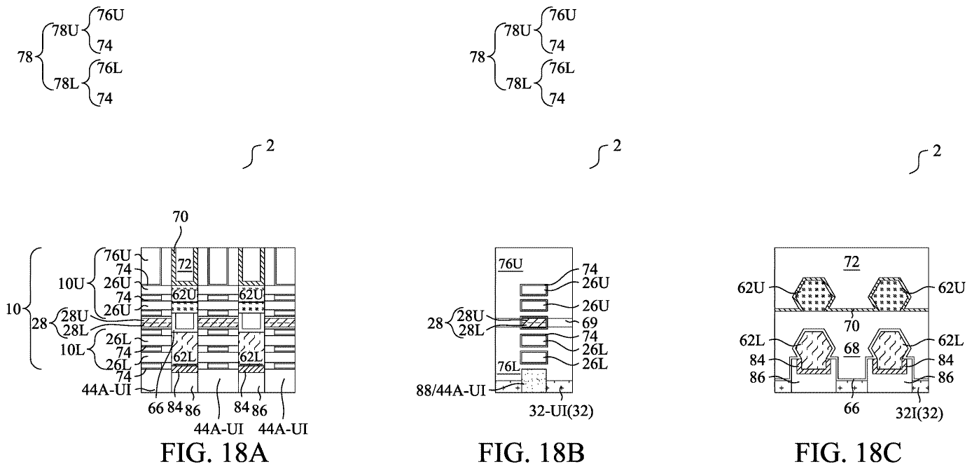

The implantation process may result in the top portions of gate spacers 45G to be implanted, and hence comprise the implanted dopant. The bottom portions of the gate spacers 45G may not be implanted. In the resulting CFET, since the top portions of the gate spacers 45G may be removed through subsequent CMP processes, the resulting CFET may not (or may) comprise the dopant in the upper portions of the resulting gate spacer 45G. In the resulting structure as shown in FIG. 18A, the top portions of the gate spacers 45G thus may be free from, or may include, the dopant, and the bottom portions of the gate spacers 45G may be free from the dopant. When including the dopant, the upper portions of gate spacers 45G may have gradually reduced dopant concentrations in a direction from top to an intermediate portion of the gate spacers 45G. Furthermore, as shown in FIG. 10B, fin spacers 45F are also implanted, and hence comprises the implanted dopant.

In addition, some top portions of isolation regions 32, which portions are not directly underlying the implanted portions 44A-I and fin spacers 45F, are also implanted (doped) by the implantation process 48, and are referred to as the implanted (or doped) portions 32-I. Accordingly, the top portions 32-I may comprise the implanted dopant, and the dopant concentration of the implanted dopant is higher than the respective lower portions, which are referred to as un-implanted portions 32-UI. The lower portions 32-UI may thus be free from the implanted dopant.

Due to the masking of fin spacers 45F, the doped top portions 32-I may be laterally spaced apart from the portions 20B and 20C of the strip portions of the substrate 20. Also, some portions of isolation regions 32 directly underlying dummy gate stacks 42 and gate spacers 45G are not implanted, and are referred to as un-implanted portions 32-UI, which are shown in the final structure as in FIG. 18B.

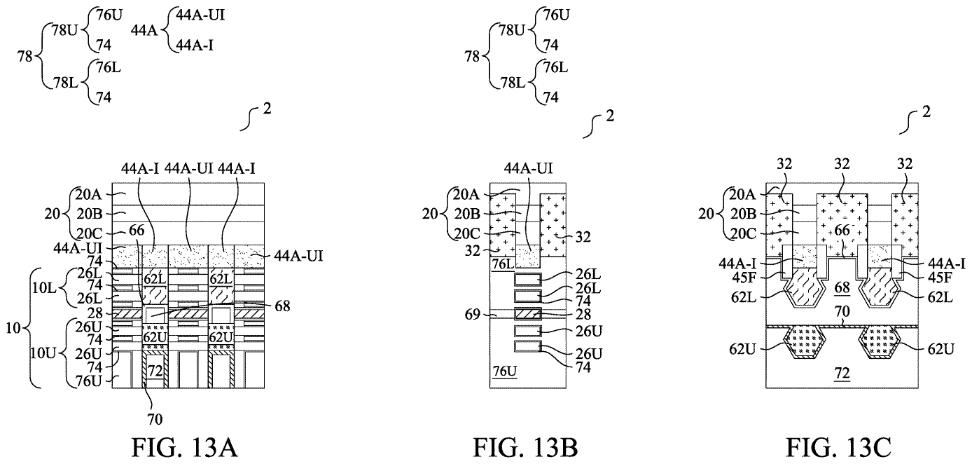

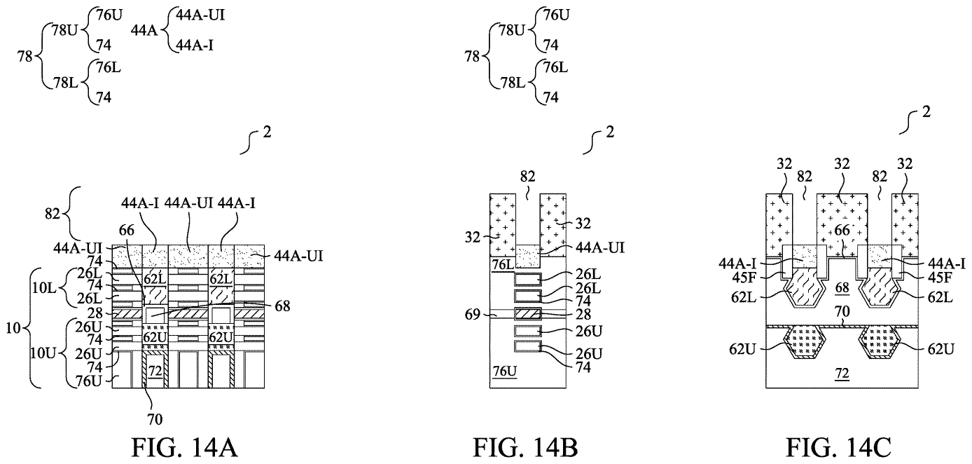

The implantation process 48 has several functions. First, it creates and enlarges etching selectivity between the implanted portions 44A-I and the un-implanted portions 44A-UI, so that in the subsequent removal of the implanted portions 44A-I (FIGS. 13C and 14C), the respective etching process may be selective and self-aligned, and the un-implanted portions 44A-UI are not removed. Second, when some dopant such as silicon is implanted into the implanted portions 44A-I, the epitaxy of the lower source/drain regions will be easier.

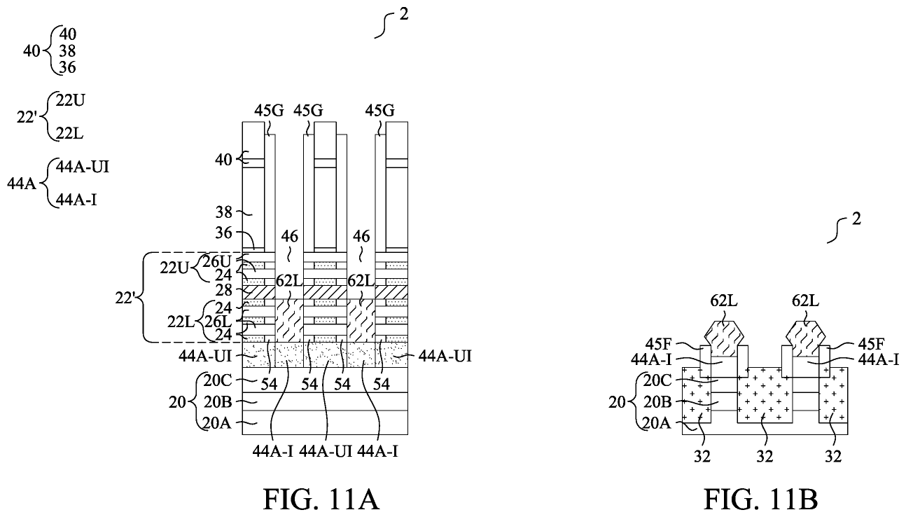

In FIGS. 11A and 11B, lower epitaxial source/drain regions 62L are formed in the lower portions of the source/drain recesses 46. The respective process is illustrated as process 224 in the process flow 200 as shown in FIG. 19. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants

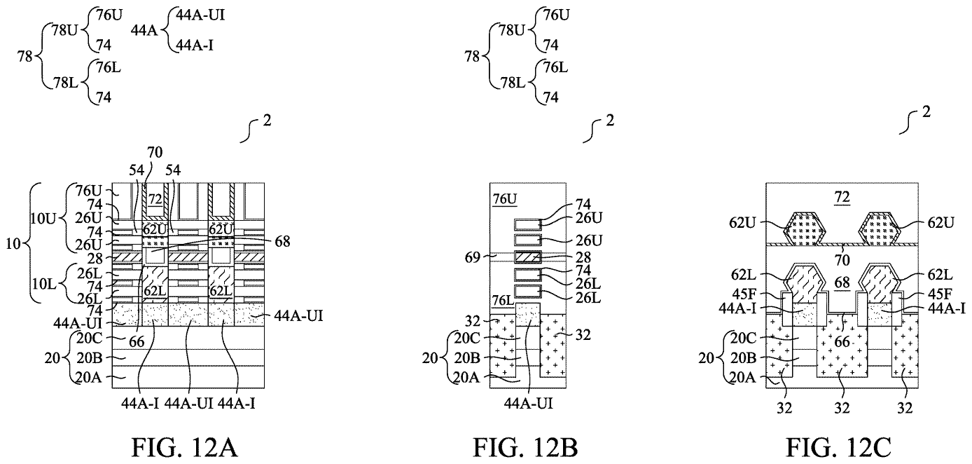

In FIGS. 12A, 12B, and 12C, a first contact etch stop layer (CESL) 66 and a first ILD 68 are formed. The respective process is illustrated as process 226 in the process flow 200 as shown in FIG. 19. FIGS. 12A and 12C illustrate the same cross-sections as shown in FIGS. 11A and 11B, respectively. FIG. 12B illustrates the cross-section cutting through the resulting replacement gate stacks, which replace the dummy gate stacks 42 as shown in FIG. 11A.

The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

Upper epitaxial source/drain regions 62U are formed in the upper portions of the source/drain recesses 46. The respective process is illustrated as process 228 in the process flow 200 as shown in FIG. 19. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type dopant (such as phosphorus, with a concentration higher than about 1E21/cm³, for example) or a p-type dopant (such as boron, with a concentration higher than about 5E20/cm³, for example).

A second CESL 70 and a second ILD 72 are formed. The materials and the formation methods may be similar to the materials and the formation methods of first CESL 66 and first ILD 68, respectively, and are not discussed in detail herein. The respective process is illustrated as process 230 in the process flow 200 as shown in FIG. 19. The formation process may include depositing the layers for CESL 70 and ILD 72, and performing a planarization process to remove the excess portion of the corresponding layers. After the planarization process, top surfaces of the second ILD 72, the gate spacers 45G, and the dummy gate stacks 42 are coplanar (within process variations). The planarization process may remove masks 40, or leave hard masks 40 unremoved.

The dummy gate stacks 42 are then removed in one or more etching processes, so that recesses (occupied by replacement gate stacks 78) are formed. The remaining portions of the dummy nanostructures 24 are then removed through etching, so that the recesses extend between the semiconductor layers 26U and 26L.

Replacement gate stacks 78 are then formed in the recesses. The respective process is illustrated as process 232 in the process flow 200 as shown in FIG. 19. The replacement gate stacks 78 include lower gate stacks 78L and upper gate stacks 78U. The lower gate stacks 78L include gate dielectrics 74 and lower gate electrodes 76L. The upper gate stacks 78U include gate dielectrics 74 and upper gate electrodes 76U.

The gate dielectrics 74 may include interfacial layers, which may include an oxide such as silicon oxide or a metal oxide, a silicate such as a metal silicate, combinations thereof, multi-layers thereof, or the like. The gate dielectrics 74 may also include high-k dielectric layers, which may be formed of or comprise a metal oxide or a silicate of a metal selected from hafnium, aluminum, lanthanum, zirconium, barium, titanium, lead, and combinations thereof.

The gate electrodes 76L and 76U may include work function layers suit to the conductivity type of the respective lower FETs and upper FETs, and may include TiN, TiAl, Mo, Ru, or the like. Dielectric layer 69 (FIG. 12B) may be formed to separate the lower gate electrodes 76L from the upper gate electrodes 76U, and may comprise SiOCN, for example, with carbon atomic percentage smaller than about 6 percent.

Upper FET 10U and lower FET 10L are thus formed. The lower FET 10L includes lower source/drain regions 62L, semiconductor layers 26L as channel regions, and lower gate stacks 78L. The upper FET 10U includes upper source/drain regions 62U, semiconductor layers 26U as channel regions, and upper gate stacks 78U. Upper FET 10U and lower FET 10L collectively form CFET 10.

The wafer 2 is then flipped upside down, and the resulting structure is shown in FIGS. 13A, 13B, and 13C. The respective process is illustrated as process 234 in the process flow 200 as shown in FIG. 19. Wafer 2 may also be thinned from backside if needed, and semiconductor layer 20A may be thinned (which is referred to as a demesa process), for example, in a CMP process or a mechanical polish process.

Next, an anisotropic etching process is performed to remove semiconductor layer 20A, 20B, and 20C, exposing the bottom dielectric isolation layer 44A, as shown in FIGS. 14A, 14B, and 14C. Backside contact openings 82 are thus formed. The respective process is illustrated as process 236 in the process flow 200 as shown in FIG. 19. The etching is selective so that the semiconductor layer 20A, 20B, and 20C are removed, while the bottom dielectric isolation layers 44A are not etched. The etching may also be performed through an isotropic etching process or an anisotropic etching process.

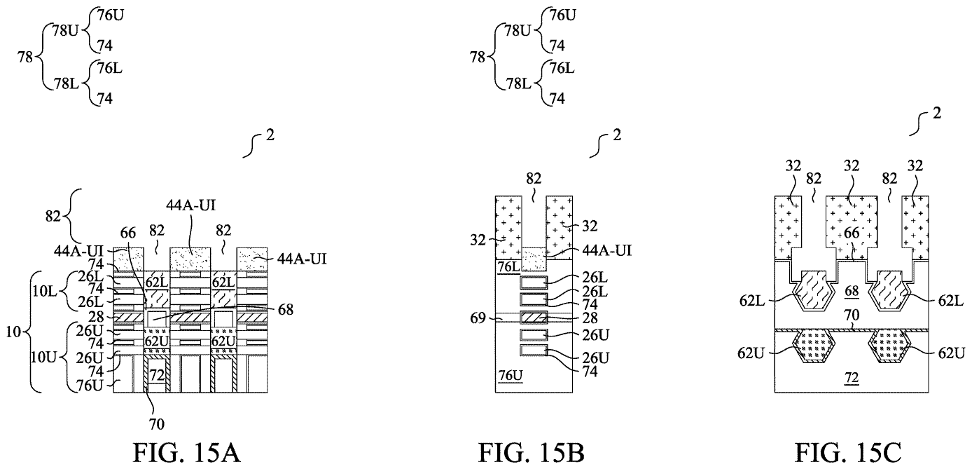

Referring to FIGS. 15A, 15B, and 15C, the implanted portions 44A-I of the bottom dielectric isolation layer 44A are removed, which may be achieved through an isotropic etching process such as a dry etching process or a wet etching process. The respective process is illustrated as process 238 in the process flow 200 as shown in FIG. 19. In addition, fin spacers 45F, which are also implanted, may be removed through etching. The etching processes may be performed through an isotropic etching process(es) using an etching chemical (such as an etching gas) that does not etch lower source/drain regions 62L. The etching is selective, so that the un-implanted portions 44A-UI are not etched. Also, isolation regions 32 are not etched. Accordingly, the bottom portions of contact openings 82 are expanded, an shown in FIG. 15C.

As shown in FIG. 15C, due to the removal of fin spacers 45F, the contact openings 82 may extend lower than the top surfaces of the lower source/drain regions 62L. The top surfaces and some sidewalls of the lower source/drain regions 62L are also exposed.

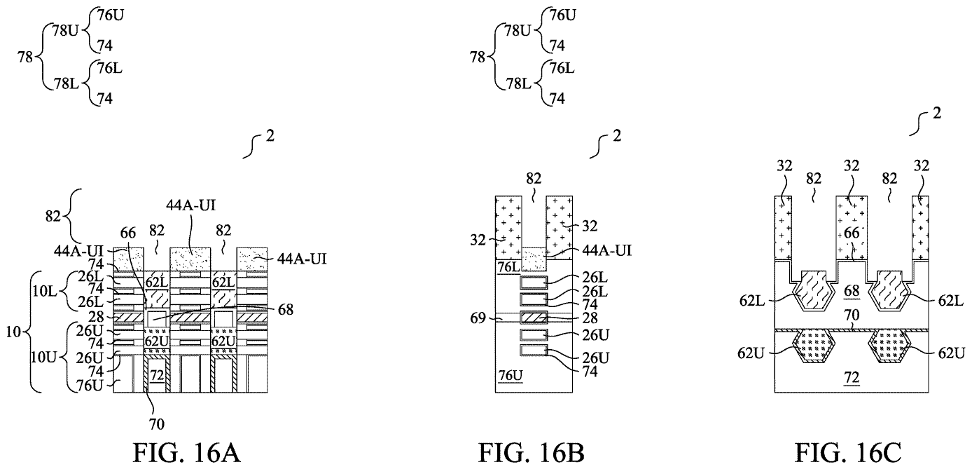

In a subsequent process, a widening process may be performed to widen the upper portions of contact openings 82. The respective process is illustrated as process 240 in the process flow 200 as shown in FIG. 19. The resulting structure is shown in FIGS. 16A, 16B, and 16C. The widening process may be performed through an isotropic etching process using an etching chemical (such as an etching gas) that etches isolation regions 32, but not lower source/drain regions 62L. The upper portions of contact openings 82 are expanded more than the lower portions of contact openings 82.

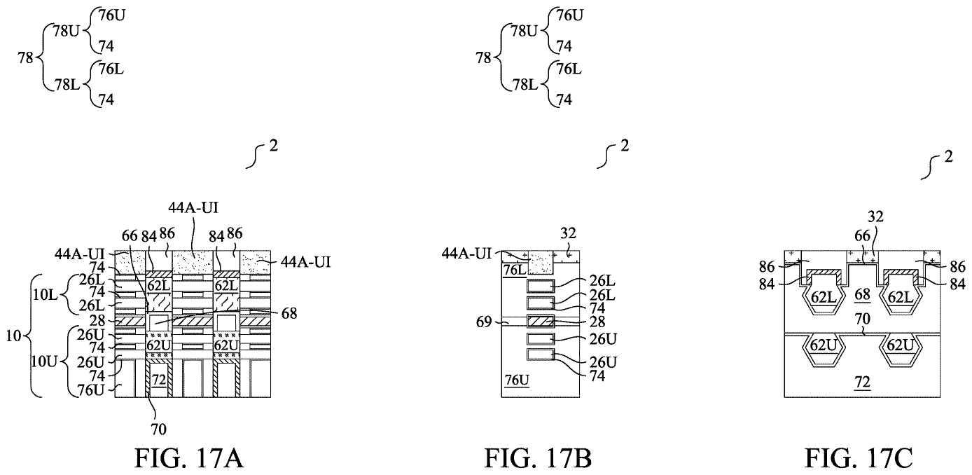

As also shown in FIGS. 17A, 17B, and 17C, silicide layers 84 and backside source/drain contact plugs 86 are formed, and electrically connect to the lower source/drain regions 62L. The respective process is illustrated as process 242 in the process flow 200 as shown in FIG. 19.

FIGS. 18A, 18B, and 18C illustrate an upside-down view of the structure shown in FIGS. 17A, 17B, and 17C. In addition, a backside gate contact plug 88 may be formed. The formation of the backside gate contact plug 88 may include etching a portion of the un-implanted portions 44A-UI, which portion is vertically aligned to (semiconductor layers (channel regions) 26L, and forming the backside gate contact plug 88 in the respective openings. The etching may be isotropic. In FIG. 18B, the symbol “88/44A-UI” represents the corresponding region may be a backside gate contact plug 88 or an un-implanted portion 44A-UI.

In FIGS. 18B and 18C, the implanted portions 32-UI (which may be free from the implanted dopant introduced by the implantation process 48 as shown in FIGS. 10A and 10B) of isolation regions 32 and implanted portions 32-I (which comprises the implanted dopant) of isolation regions 32 are also illustrated.

Advantageously, since both of the backside source/drain contact plugs 86 and the backside gate contact plug 88 are formed in the recesses that are left by the removed implanted portions and un-implanted portions, respectively, of the bottom dielectric isolation layers 44A, the top surfaces of the backside source/drain contact plugs 86 and backside gate contact plug 88 throughout wafer 2 may be at the same level or substantially the same level.

The embodiments of the present disclosure have some advantageous features. By forming bottom dielectric isolation layers, which are formed based on the same planar semiconductor sacrificial layer throughout a wafer, the depth uniformity of backside source/drain contact plugs and the backside gate contact plugs throughout the wafer is improved. The bottom dielectric isolation layers may also be used as the etch stop layers for the formation of source/drain recesses, and hence the depth uniformity of the source/drain regions throughout the wafer is improved.

In accordance with some embodiments of the present disclosure, a method comprises forming a wafer comprising a substrate; a sacrificial layer over the substrate; and a multilayer stack over the sacrificial layer; performing a first etching process on the multilayer stack and the sacrificial layer to form a patterned multilayer stack; replacing a part of the sacrificial layer in the patterned multilayer stack with a bottom dielectric isolation layer; performing a second etching process on the patterned multilayer stack to form a source/drain recess, wherein a surface of the bottom dielectric isolation layer is exposed to the source/drain recess; forming a lower source/drain region in the source/drain recess; forming an upper source/drain region in the source/drain recess and over the lower source/drain region; removing the substrate from a backside of the wafer to reveal the bottom dielectric isolation layer; removing a portion of the bottom dielectric isolation layer to form a backside contact opening; and forming a source/drain silicide layer on the lower source/drain region and in the backside contact opening.

In an embodiment, the method further comprises, after the second etching process, performing an implantation process to implant a first portion of the bottom dielectric isolation layer, wherein a second portion of the bottom dielectric isolation layer is protected from being implanted. In an embodiment, in the removing the portion of the bottom dielectric isolation layer to form the backside contact opening, the first portion of the bottom dielectric isolation layer is removed, and the second portion of the bottom dielectric isolation layer remains.

In an embodiment, the implantation process comprises implanting silicon. In an embodiment, the removing the portion of the bottom dielectric isolation layer comprises an isotropic etching process. In an embodiment, the method further comprises depositing a gate spacer layer on a top surface and sidewalls of the patterned multilayer stack, wherein the bottom dielectric isolation layer is formed in a same deposition process as the depositing the gate spacer layer.

In an embodiment, the method further comprises depositing a gate spacer layer on a top surface and sidewalls of the patterned multilayer stack, wherein the bottom dielectric isolation layer is formed in a different deposition process than the depositing the gate spacer layer. In an embodiment, the method further comprises removing a plurality of sacrificial layers in the patterned multilayer stack to form a recess; and forming a replacement gate stack in the recess.

In accordance with some embodiments of the present disclosure, a method comprises forming a dummy gate stack over a top surface and sidewalls of an elongated multilayer strip; etching the elongated multilayer strip to form a source/drain recess using a bottom dielectric isolation layer as an etch stop layer, wherein the elongated multilayer strip comprises a lower multilayer stack; a dielectric layer over the lower multilayer stack; and an upper multilayer stack over the dielectric layer; performing an implantation process through the source/drain recess, wherein a first portion of the bottom dielectric isolation layer is implanted to form an implanted region, and a second portion of the bottom dielectric isolation layer underlying the dummy gate stack is protected by the dummy gate stack from being implanted, and is an un-implanted region; forming a lower source/drain region in the source/drain recess, wherein the lower source/drain region contacts a first semiconductor layer in the lower multilayer stack; forming a upper source/drain region in the source/drain recess and over the lower source/drain region, wherein the upper source/drain region contacts a second semiconductor layer in the upper multilayer stack; removing a substrate to reveal the bottom dielectric isolation layer; performing a selective etching process to remove the implanted region and to form a backside contact opening, wherein the lower source/drain region is revealed through the backside contact opening; and forming a silicide layer and a backside contact plug in the backside contact opening.

In an embodiment, the un-implanted region remains after the selective etching process. In an embodiment, the selective etching process is performed through an isotropic etching process, and wherein both of the implanted region and the un-implanted region are exposed to an etching chemical used for the selective etching process. In an embodiment, the method further comprises bonding a first wafer and a second wafer to form a third wafer comprising a multilayer stack; and patterning the multilayer stack to form the elongated multilayer strip. In an embodiment, the dielectric layer comprises a first sub dielectric layer, and a second sub dielectric layer over the first sub dielectric layer.

In an embodiment, in the implantation process, a fin spacer on a sidewall of the implanted region is also implanted. In an embodiment, in the selective etching process, the fin spacer is removed. In an embodiment, the method further comprises depositing the bottom dielectric isolation layer; and depositing a gate spacer layer on a sidewall of the elongated multilayer strip, wherein the bottom dielectric isolation layer and the gate spacer layer are deposited in a same deposition process. In an embodiment, the method further comprises removing a semiconductor sacrificial layer to leave a space between the substrate and the lower multilayer stack, wherein the bottom dielectric isolation layer is deposited into the space.

In accordance with some embodiments of the present disclosure, a structure comprises a lower transistor comprising a lower source/drain region; a lower semiconductor layer aside of and contacting the lower source/drain region; and a lower gate stack encircling the lower semiconductor layer; a dielectric layer over the lower gate stack and the lower semiconductor layer; an upper transistor comprising an upper source/drain region overlapping the lower source/drain region; an upper semiconductor layer aside of and contacting the upper source/drain region; and an upper gate stack encircling the upper semiconductor layer; and a silicide layer underlying and contacting the lower source/drain region, wherein the silicide layer has a U-shape in a first cross-section of the structure.

In an embodiment, in a second cross-section of the structure, wherein the second cross-section is perpendicular to the first cross-section, first edges of the silicide layer are vertically aligned to respective second edges of the silicide layer. In an embodiment, the structure further comprises a gate spacer on a sidewall of the upper gate stack; and a bottom dielectric isolation layer underlying and contacting the lower gate stack, wherein the gate spacer and the bottom dielectric isolation layer comprise a same dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a wafer comprising a patterned multilayer stack over a bottom dielectric isolation layer;
performing an etching process on the patterned multilayer stack to form a source/drain recess, wherein a surface of the bottom dielectric isolation layer is exposed to the source/drain recess;
performing an implantation process to implant a dopant into an exposed portion of the bottom dielectric isolation layer to form an implanted portion; and
forming a lower source/drain region in the source/drain recess and over the implanted portion.

2. The method of claim 1 further comprising forming an upper source/drain region in the source/drain recess and over the lower source/drain region.

3. The method of claim 1 further comprising:
removing a substrate from a backside of the wafer to reveal the bottom dielectric isolation layer;
removing the implanted portion of the bottom dielectric isolation layer to form a backside contact opening; and
forming a source/drain silicide layer on the lower source/drain region and in the backside contact opening.

4. The method of claim 3, wherein the implanted portion of the bottom dielectric isolation layer is removed through an isotropic etching process.

5. The method of claim 3, wherein after the implanted portion of the bottom dielectric isolation layer is removed, un-implanted portions of the bottom dielectric isolation layer remain.

6. The method of claim 1 further comprising:
forming the wafer comprising a substrate, a sacrificial layer over the substrate, and a multilayer stack over the sacrificial layer;
performing an additional etching process on the multilayer stack and the sacrificial layer to form the patterned multilayer stack; and
replacing a part of the sacrificial layer in the patterned multilayer stack with a dielectric material to form the bottom dielectric isolation layer.

7. The method of claim 1, wherein the dopant is selected from the group consisting of Si, C, O, P, N, B, F, As, and combinations thereof.

8. The method of claim 7, wherein the dopant comprises silicon.

9. The method of claim 1 further comprising:
depositing a gate spacer layer on a top surface and sidewalls of the patterned multilayer stack, wherein the bottom dielectric isolation layer is formed in a same deposition process as the depositing the gate spacer layer.

10. The method of claim 1 further comprising:
depositing a gate spacer layer on a top surface and sidewalls of the patterned multilayer stack, wherein the bottom dielectric isolation layer is formed through a different deposition process than the depositing the gate spacer layer.

11. The method of claim 1 further comprising:
removing a plurality of sacrificial semiconductor layers in the patterned multilayer stack to form a recess; and
forming a replacement gate stack in the recess.

12. A method comprising:
forming a dummy gate stack over a top surface and sidewalls of an elongated multilayer strip;
etching the elongated multilayer strip to form a source/drain recess, wherein a bottom dielectric isolation layer is used as an etch stop layer;
performing an implantation process through the source/drain recess, wherein:
a first portion of the bottom dielectric isolation layer is implanted to form an implanted region; and
a second portion of the bottom dielectric isolation layer underlying the dummy gate stack is protected by the dummy gate stack from being implanted, and is an un-implanted region; and
forming a lower source/drain region in the source/drain recess, wherein the lower source/drain region contacts a first semiconductor layer in the elongated multilayer strip.

13. The method of claim 12 further comprising:
forming an upper source/drain region in the source/drain recess and over the lower source/drain region, wherein the upper source/drain region contacts a second semiconductor layer in the elongated multilayer strip.

14. The method of claim 12, wherein the elongated multilayer strip comprises:
a lower multilayer stack, wherein the lower source/drain region contacts the lower multilayer stack;
a dielectric layer over the lower multilayer stack; and
an upper multilayer stack over the dielectric layer.

15. The method of claim 12 further comprising:
removing a substrate to reveal the bottom dielectric isolation layer;
performing a selective etching process to remove the implanted region and to form a backside contact opening, wherein the lower source/drain region is revealed through the backside contact opening; and
forming a silicide layer and a backside contact plug in the backside contact opening.

16. The method of claim 15, wherein the un-implanted region remains after the selective etching process.

17. The method of claim 15, wherein the selective etching process is performed through an isotropic etching process, and wherein both of the implanted region and the un-implanted region are exposed to an etching chemical used for the selective etching process.

18. A method comprising:
forming a wafer comprising:
a substrate;
a bottom dielectric isolation layer over the substrate; and
a patterned multilayer stack over the bottom dielectric isolation layer;
etching the patterned multilayer stack to form a source/drain recess, wherein a surface of the bottom dielectric isolation layer is exposed to the source/drain recess;
forming a source/drain region in the source/drain recess;
removing the substrate to reveal the bottom dielectric isolation layer;
performing an etching process, wherein a first portion of the bottom dielectric isolation layer exposed to an etching chemical is removed to form a backside contact opening, and a second portion of the bottom dielectric isolation layer that is also exposed to the etching chemical remains after the etching process; and
forming a source/drain silicide layer on the source/drain region and in the backside contact opening.

19. The method of claim 18 further comprising, at a time after the source/drain recess is formed and before the source/drain region is formed, performing an implantation process to implant a dopant into the first portion of the bottom dielectric isolation layer, wherein the second portion of the bottom dielectric isolation layer is protected from the implantation process.

20. The method of claim 18, wherein the etching process is isotropic.
